(19) United States
(12) Patent Application Publication
(10) Pub. No.: US 2009/0309149 A1
(43) Pub. Date: Dec. 17, 2009

(54) Memory cell arrangements and methods for manufacturing a memory cell arrangement

(76) Inventors: Thomas Nirschl, Munich (DE); Christian Peters, Vaterstetten (DE); Robert Strenz, Radebeul (DE)

Correspondence Address: SLATER & MATSIL LLP, 17950 PRESTON ROAD, SUITE 1000, DALLAS, TX, 75252, US

(21) Appl. No.: 12/138,200

(22) Filed: Jun. 12, 2008

(51) Int. Cl. H01L 29/788; H01L 21/336

(52) U.S. Cl. 257/315; 438/257; 257/E21.409; 257/E29.3

(57) ABSTRACT

In an embodiment, a memory cell arrangement is provided which may include a charge storing memory cell comprising a first active area running along a first direction, a second active area disposed next to the charge storing memory cell, the second active area running along a second direction, the second direction being different from the first direction, and a select structure disposed above the second active area configured to control a current flow through the second active area.

### TECHNICAL FIELD

Embodiments relate generally to memory cell arrangements and to methods for manufacturing a memory cell arrangement.

### BACKGROUND

By way of example, for embedding memory modules into low cost applications or circuits, a minimization of process complexity and chip area is an important optimization task. In order to achieve this, in a conventional memory cell arrangement, so-called source-side injection (SSI) may be used as a write method to reduce peripheral circuit overhead. However, source-side injection using a spacer shaped select gate in a memory cell arrangement is rather difficult to scale. Therefore, for advanced technology nodes, the area advantage of an SSI memory cell arrangement vanishes compared to a uniform channel program (UCP) memory cell arrangement.

In a conventional source-side injection memory cell arrangement, in each memory cell, two transistors are provided, a floating gate transistor as the transistor which stores the information, and a select transistor to control the individual access (for a read operation, a programming operation or an erase operation) to the floating gate transistor. In this two transistor memory cell, an electrical field is generated suitable for injecting charge carriers into the floating gate during a programming operation or an erase operation.

However, such a two transistor memory cell usually requires a large area on a semiconductor chip. There is a need to reduce the size of a memory cell such as e.g. a two transistor memory cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a computer system having a memory cell arrangement in accordance with an embodiment;

FIG. 2 shows a memory cell arrangement in accordance with an embodiment;

FIG. 3 shows a top view of a portion of the memory cell field of the memory cell arrangement of FIG. 2 in accordance with an embodiment;

FIG. 4 shows a cross sectional view of the portion of the memory cell field of the memory cell arrangement of FIG. 2 taken along a cross section line A-A′ in FIG. 3, in accordance with an embodiment;

FIG. 5 shows a top view of a portion of the memory cell field of the memory cell arrangement of FIG. 2 in accordance with an embodiment illustrating a read operation;

FIG. 6 shows a top view of a portion of the memory cell field of the memory cell arrangement of FIG. 2 in accordance with an embodiment illustrating a programming operation;

FIG. 7 shows a cross sectional view of the portion of the memory cell field of the memory cell arrangement of FIG. 2 taken along a cross section line A-A′ in FIG. 3, in accordance with an embodiment at a first stage of its manufacturing;

FIG. 8 shows a cross sectional view of the portion of the memory cell field of the memory cell arrangement of FIG. 2 taken along a cross section line A-A′ in FIG. 3, in accordance with an embodiment at a second stage of its manufacturing;

FIG. 9 shows a cross sectional view of the portion of the memory cell field of the memory cell arrangement of FIG. 2 taken along a cross section line A-A′ in FIG. 3, in accordance with an embodiment at a third stage of its manufacturing;

FIG. 10 shows a cross sectional view of the portion of the memory cell field of the memory cell arrangement of FIG. 2 taken along a cross section line A-A′ in FIG. 3, in accordance with an embodiment at a fourth stage of its manufacturing;

FIG. 11 shows a cross sectional view of the portion of the memory cell field of the memory cell arrangement of FIG. 2 taken along a cross section line A-A′ in FIG. 3, in accordance with an embodiment at a fifth stage of its manufacturing;

FIG. 12 shows a cross sectional view of the portion of the memory cell field of the memory cell arrangement of FIG. 2 taken along a cross section line A-A′ in FIG. 3, in accordance with an embodiment at a sixth stage of its manufacturing;

FIG. 13 shows a flow diagram illustrating a method for manufacturing a memory cell arrangement in accordance with an embodiment; and

FIG. 14 shows a flow diagram illustrating a method for manufacturing a memory cell arrangement in accordance with another embodiment.

### DETAILED DESCRIPTION OF ILLUSTRATIVE EMBODIMENTS

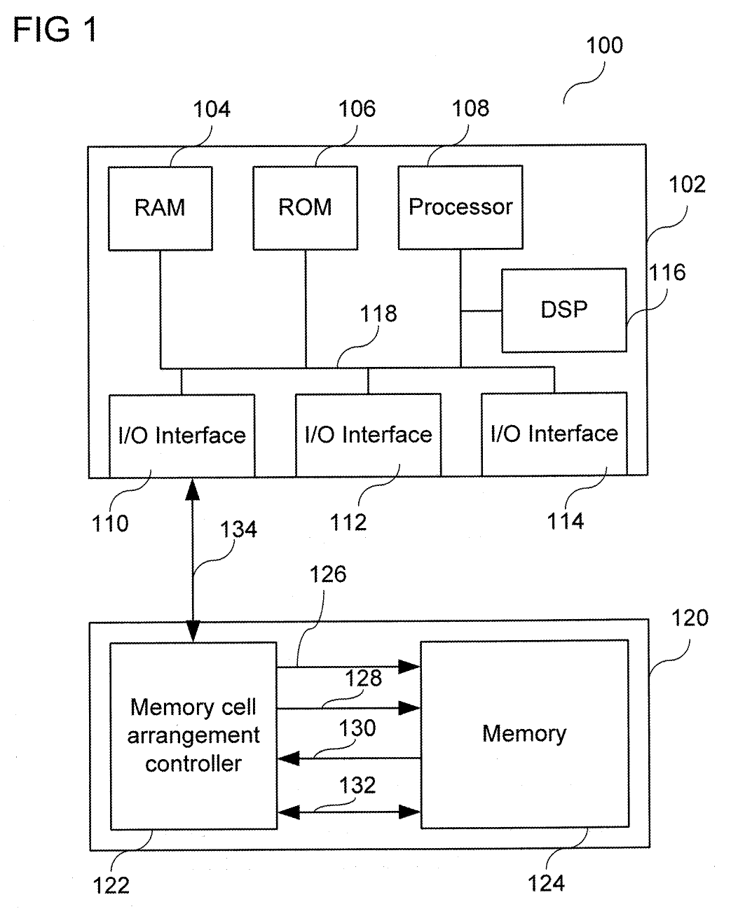

FIG. 1 shows a computer system 100 having a computer arrangement 102 and a memory cell arrangement 120 in accordance with an embodiment.

In various embodiments, the computer arrangement 102 may be configured as or may include any device having a processor, e.g. having a programmable processor such as e.g. a microprocessor (e.g. a CISC (complex instruction set computer) microprocessor or a RISC (reduced instruction set computer) microprocessor). In various embodiments, the computer arrangement 102 may be configured as or may include a personal computer, a workstation, a laptop, a notebook, a personal digital assistant (PDA), a radio telephone (e.g. a wireless radio telephone or a mobile radio telephone), a camera (e.g. an analog camera or a digital camera), a smart card, or another device having a processor (such as e.g. a household appliance (such as e.g. a washing machine, a dishwashing machine, etc.)).

In an embodiment, the computer arrangement 102 may include one or a plurality of computer arrangement-internal random access memories (RAM) 104, e.g. one or a plurality of computer arrangement-internal dynamic random access memories (DRAM), in which for example data to be processed may be stored. Furthermore, the computer arrangement 102 may include one or a plurality of computer arrangement-internal read only memories (ROM) 106, in which for example the program code may be stored, which should be executed by a processor 108 (e.g. a processor as described above), which may also be provided in the computer arrangement 102.

Furthermore, in an embodiment, one or a plurality of input/output interfaces 110, 112, 114 (in FIG. 1, there are shown three input/output interfaces, in alternative embodiments, e.g. one, two, four, or even more than four input/output interfaces may be provided) configured to connect one or a plurality of computer arrangement-external devices (such as e.g. additional memory, one or a plurality of communication devices, one or a plurality of additional processors) to the computer arrangement 102, may be provided in the computer arrangement 102.

The input/output interfaces 110, 112, 114 may be implemented as analog interfaces and/or as digital interfaces. The input/output interfaces 110, 112, 114 may be implemented as serial interfaces and/or as parallel interfaces. The input/output interfaces 110, 112, 114 may be implemented as one or a plurality of circuits, which implements or implement a respective communication protocol stack in its functionality in accordance with the communication protocol which is respectively used for data transmission. Each of the input/output interfaces 110, 112, 114 may be configured in accordance with any communication protocol. In an embodiment, each of the input/output interfaces 110, 112, 114 may be implemented in accordance with one of the following communication protocols:
an ad hoc communication protocol such as e.g. Firewire or Bluetooth;
a communication protocol for a serial data transmission such as e.g. RS-232, Universal Serial Bus (USB) (e.g. USB 1.0, USB 1.1, USB 2.0, USB 3.0);
any other communication protocol such as e.g. Infrared Data Association (IrDA).

In an embodiment, the first input/output interface 110 is a USB interface (in alternative embodiments, the first input/output interface 110 may be configured in accordance with any other communication protocol such as e.g. in accordance with a communication protocol which has been described above).

In an embodiment, the computer arrangement 102 optionally may include an additional digital signal processor (DSP) 116, which may be provided e.g. for digital signal processing. Furthermore, the computer arrangement 102 may include additional communication modules (not shown) such as e.g. one or a plurality of transmitters, one or a plurality of receivers, one or a plurality of antennas, and so on.

The computer arrangement 102 may also include additional components (not shown), which are desired or required in the respective application.

In an embodiment, some or all of the circuits or components provided in the computer arrangement 102 may be coupled with each other by means of one or a plurality of computer arrangement-internal connections 118 (for example by means of one or a plurality of computer busses) configured to transmit data and/or control signals between the respectively coupled circuits or components.

Furthermore, as has been described above, the computer system 100, in accordance with an embodiment, may include the memory cell arrangement 120.

The memory cell arrangement 120 may in an embodiment be configured as an integrated circuit. The memory cell arrangement 120 may further be provided in a memory module having a plurality of integrated circuits, wherein at least one integrated circuit of the plurality of integrated circuits includes a memory cell arrangement 120, as will be described in more detail below. The memory module may be a stackable memory module, wherein some of the integrated circuit may be stacked one above the other. In an embodiment, the memory cell arrangement 120 is configured as a memory card.

In an embodiment, the memory cell arrangement 120 may include a memory cell arrangement controller 122 (for example implemented by means of hard wired logic and/or by means of one or a plurality of programmable processors, e.g. by means of one or a plurality of programmable processors such as e.g. one or a plurality of programmable microprocessors (e.g. CISC (complex instruction set computer) microprocessor(s) or RISC (reduced instruction set computer) microprocessor(s)).

The memory cell arrangement 120 may further include a memory 124 having a plurality of memory cells. The memory 124 will be described in more detail below.

In an embodiment, the memory cell arrangement controller 122 may be coupled with the memory 124 by means of various connections. Each of the connections may include one or a plurality of lines and may thus have a bus width of one or a plurality of bits. Thus, by way of example, an address bus 126 may be provided, by means of which one or a plurality of addresses of one or a plurality of memory cells may be provided by the memory cell arrangement controller 122 to the memory 124, on which an operation (e.g. an erase operation, a write operation, a read operation, an erase verify operation, or a write verify operation, etc.) should be carried out. Furthermore, a data write connection 128 may be provided, by means of which the information to be written into the respectively addressed memory cell may be supplied by the memory cell arrangement controller 122 to the memory 124. Furthermore, a data read connection 130 may be provided, by means of which the information stored in the respectively addressed memory cell may be read out of the memory 124 and may be supplied from the memory 124 to the memory cell arrangement controller 122 and via the memory cell arrangement controller 122 to the computer arrangement 102, or, alternatively, directly to the computer arrangement 102 (in which case the first input/output interface 110 would directly be connected to the memory 124). A bidirectional control/state connection 132 may be used for providing control signals from the memory cell arrangement controller 122 to the memory 124 or for supplying state signals representing the state of the memory 124 from the memory 124 to the memory cell arrangement controller 122.

In an embodiment, the memory cell arrangement controller 122 may be coupled to the first input/output interface 110 by means of a communication connection 134 (e.g. by means of a USB communication connection).

In an embodiment, the memory 124 may include one chip or a plurality of chips. Furthermore, the memory cell arrangement controller 122 may be implemented on the same chip (or die) as the components of the memory 124 or on a separate chip (or die).

In another embodiment, the memory cell arrangement 120 may be integrated in the computer arrangement 102. By way of example, the memory cell arrangement 120 may be provided instead of or in addition to the internal read only memories (ROM) 106. In this example, the input/output interfaces 110, 112, 114 may not be provided and the interface may be a direct interface to the computer arrangement-internal connections 118. Thus, by way of example, the memory cell arrangement 120 may be a non-volatile memory of a smart card (as an implementation of the computer arrangement 102) or a mobile device such as e.g. a PDA or a mobile phone or another mobile device, as described above.

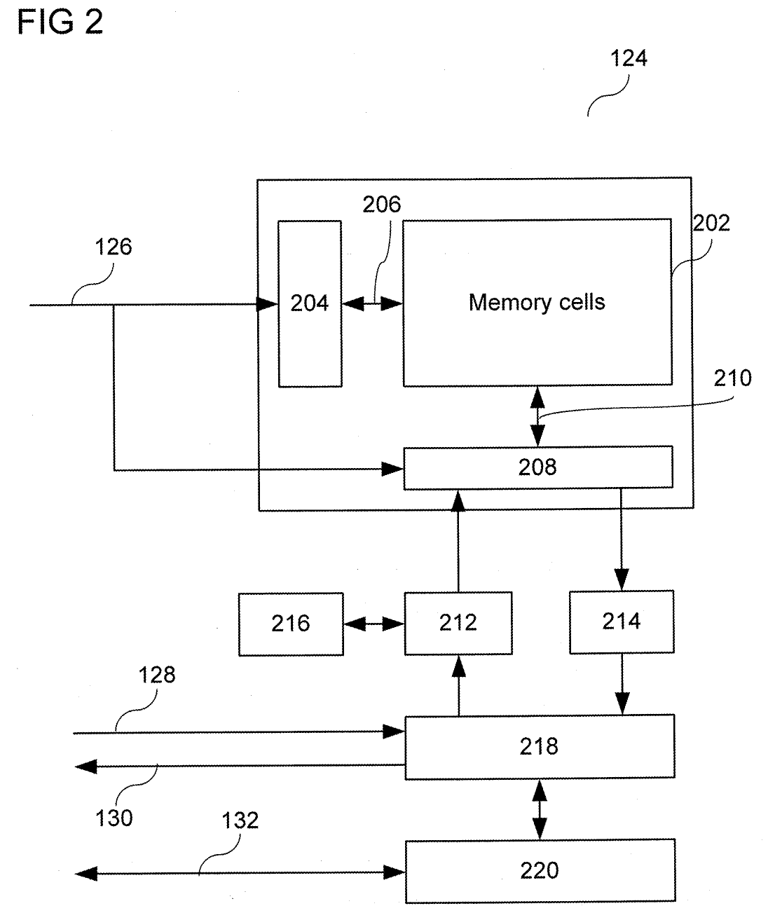

FIG. 2 shows the memory 124 of FIG. 1 in accordance with an embodiment in more detail.

In an embodiment, the memory 124 may include a memory cell field (e.g. a memory cell array) 202 having a plurality of memory cells. The memory cells may be arranged in the memory cell field 202 in the form of a matrix in rows and columns, or, alternatively, for example in zig zag form. In other embodiments, the memory cells may be arranged within the memory cell field 202 in any other manner or architecture.

In general, each memory cell may for example be coupled with a first control line (e.g. a word line) and with at least one second control line (e.g. at least one bit line).

In an embodiment, in which the memory cells are arranged in the memory cell field 202 in the form of a matrix in rows and columns, a row decoder circuit 204 configured to select at least one row control line (e.g. a word line) of a plurality of row control lines 206 in the memory cell field 202 may be provided as well as a column decoder circuit 208 configured to select at least one column control line (e.g. a bit line) of a plurality of column control lines 210 in the memory cell field 202.

In an embodiment, the memory cells are non-volatile memory cells.

A “non-volatile memory cell” may be understood as a memory cell storing data even if it is not active. In an embodiment, a memory cell may be understood as being not active e.g. if currently access to the content of the memory cell is inactive. In another embodiment, a memory cell may be understood as being not active e.g. if the power supply is inactive. Furthermore, the stored data may be refreshed on a regular timely basis, but not, as with a “volatile memory cell” every few picoseconds or nanoseconds or milliseconds, but rather in a range of hours, days, weeks or months. Alternatively, the data may not need to be refreshed at all in some designs.

Furthermore, the memory cells may be electrically erasable read only memory cells (EEPROM).

In an embodiment, the memory cells may be Flash memory cells, e.g. charge storing memory cells such as e.g. floating gate memory cells or charge trapping memory cells.

In an embodiment, each charge trapping memory cell includes a charge trapping layer structure for trapping electrical charge carriers. The charge trapping layer structure may include one or a plurality of two separate charge trapping regions. In an embodiment, the charge trapping layer structure includes a dielectric layer stack including at least one dielectric layer or at least two dielectric layers being formed above one another, wherein charge carriers can be trapped in at least one dielectric layer. By way of example, the charge trapping layer structure includes a charge trapping layer, which may include or consist of one or more materials being selected from a group of materials that consists of: aluminum oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminum, zirconium and oxygen (AlZrO). In one embodiment, the charge trapping layer structure includes a dielectric layer stack including three dielectric layers being formed above one another, e.g. a first oxide layer (e.g. silicon oxide), a nitride layer as charge trapping layer (e.g. silicon nitride) on the first oxide layer, and a second oxide layer (e.g. silicon oxide or aluminum oxide) on the nitride layer. This type of dielectric layer stack is also referred to as ONO layer stack. In an alternative embodiment, the charge trapping layer structure includes two, four or even more dielectric layers being formed above one another.

In an embodiment, the memory cells may be multi-bit memory cells. As used herein the term “multi-bit” memory cell is intended to e.g. include memory cells which are configured to store a plurality of bits by spatially separated electric charge storage regions or current conductivity regions, thereby representing a plurality of logic states.

In another embodiment, the memory cells may be multi-level memory cells. As used herein the term “multi-level” memory cell is intended to e.g., include memory cells which are configured to store a plurality of bits by showing distinguishable voltage or current levels dependent on the amount of electric charge stored in the memory cell or the amount of electric current flowing through the memory cell, thereby representing a plurality of logic states.

In an embodiment, address signals are supplied to the row decoder circuit 204 and the column decoder circuit 208 by means of the address bus 126, which is coupled to the row decoder circuit 204 and to the column decoder circuit 208. The address signals uniquely identify at least one memory cell to be selected for an access operation (e.g. for one of the above described operations). The row decoder circuit 204 selects at least one row und thus at least one row control line 206 in accordance with the supplied address signal. Furthermore, the column decoder circuit 208 selects at least one column und thus at least one column control line 210 in accordance with the supplied address signal.

The electrical voltages that are provided in accordance with the selected operation, e.g. for reading, programming (e.g. writing) or erasing of one memory cell or of a plurality of memory cells, are applied to the selected at least one row control line 206 and to the at least one column control line 210.

In the case that each memory cell is configured in the form of one or more field effect transistors (e.g. in the case of a charge storing memory cell, possibly together with a select gate structure), in an embodiment, the respective gate terminal is coupled to the row control line 206 and a first source/drain terminal is coupled to a first column control line 210. As will be described in more detail below, a select gate structure, which simultaneously illustratively also forms a common source line structure, may be provided as a second column control line 210.

In an embodiment, by way of example, for reading or for programming, a single row control line 206 and a single column control line 210 are selected at the same time and are appropriately driven for reading or programming of the thus selected memory cell. In an alternative embodiment, it may be provided to respectively select a single row control line 206 and a plurality of column lines 210 at the same time for reading or for programming, thereby allowing to read or program a plurality of memory cells at the same time. As will be described in more detail below, in various embodiments, the respective common source line structure 210 may also be selected and activated to enable a current flow through the selected common source line structure 210.

Furthermore, in an embodiment, the memory 124 includes at least one write buffer memory 212 and at least one read buffer memory 214. The at least one write buffer memory 212 and the at least one read buffer memory 214 are coupled with the column decoder circuit 208. Depending on the type of memory cell, reference memory cells 216 may be provided for reading the memory cells.

In order to program (e.g. write) a memory cell, the data to be programmed may be received by a data register 218, which is coupled with the data write connection 128, by means of the data write connection 128, and may be buffered in the at least one write buffer memory 212 during the write operation.

In order to read a memory cell, the data read from the addressed memory cell (represented e.g. by means of an electrical current, which flows through the addressed memory cell and the corresponding column control line 210, which may be compared with a current threshold value in order to determine the content of the memory cell, wherein the current threshold value may e.g. be dependent from the reference memory cells 216) are e.g. buffered in the read buffer memory 214 during the read operation. The result of the comparison und therewith the logic state of the memory cell (wherein the logic state of the memory cell represents the memory content of the memory cell) may then be stored in the data register 218 and may be provided via the data read connection 130, with which the data register 218 may be coupled.

The access operations (e.g. write operations, read operations, or erase operations) may be controlled by a memory-internal controller 220, which in turn may be controlled by the memory cell arrangement controller 122 by means of the bidirectional control/state connection 132. In an alternative embodiment, the data register 218 may directly be connected to the memory cell arrangement controller 122 by means of the bidirectional control/state connection 132 and thus directly controlled thereby. In this example, the memory-internal controller 220 may be omitted.

In an embodiment, the memory cells of the memory cell field 202 may be grouped into memory blocks or memory sectors, which may be commonly erased in an erase operation.

Furthermore, other common memory components (e.g. peripheral circuits such as e.g. charge pump circuits, etc.) may be provided in the memory 124, but they are neither shown in FIG. 1 nor in FIG. 2 for reasons of clarity.

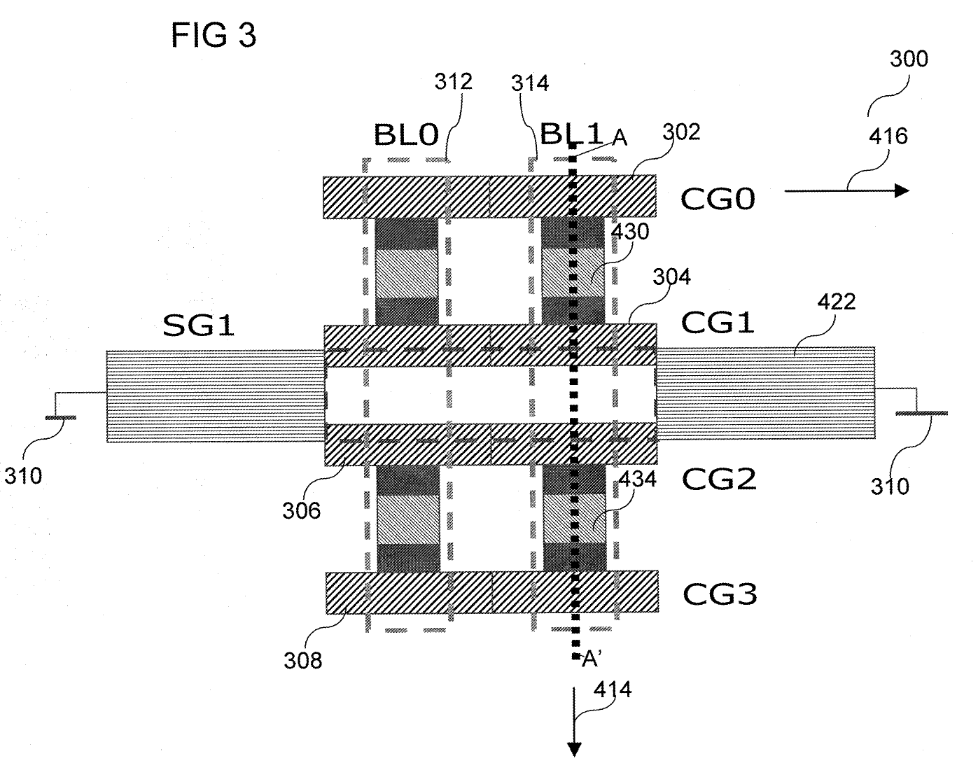

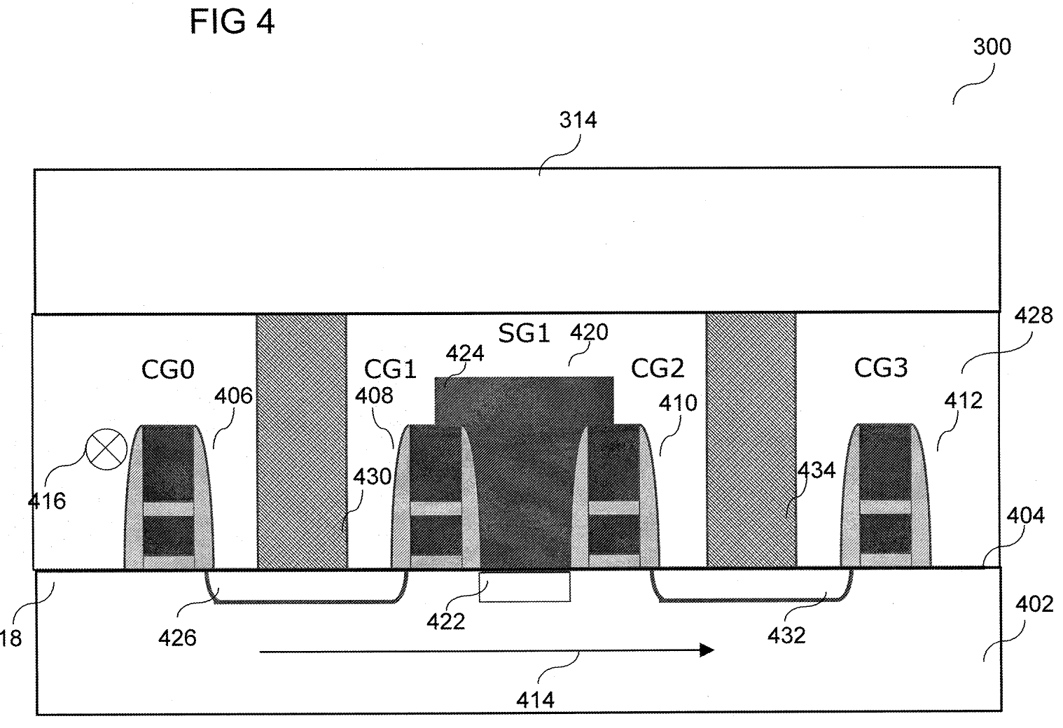

FIG. 3 shows a top view of a portion 300 of the memory cell field 202 of the memory cell arrangement 120 of FIG. 2 in accordance with an embodiment. Furthermore, FIG. 4 shows a cross sectional view of the portion 300 of the memory cell field 202 of the memory cell arrangement 120 of FIG. 2 in accordance with an embodiment taken along a cross section line A-A′ of FIG. 3.

As shown in FIG. 4, the memory cell field 202 may include one or more charge storing memory cells including a first active area 418 running along a first direction (in FIGS. 3 and 4, the first direction is symbolized by means of a first arrow 414). In the example shown in FIG. 4, four charge storing memory cells (e.g. a first charge storing memory cell 406, a second charge storing memory cell 408, a third charge storing memory cell 410, and a fourth charge storing memory cell 412), are provided arranged on an upper surface (which may be the main processing surface) 404 of a substrate 402.

In an embodiment, the substrate (e.g. a wafer substrate) 402 may be made of semiconductor materials of various types, including silicon, germanium, Group III to V or other types, including polymers, for example, although in another embodiment of the invention, other suitable materials can also be used. In an embodiment, the substrate 402 is made of silicon (doped or undoped), in an alternative embodiment of the invention, the substrate 402 is a silicon on insulator (SOI) wafer. As an alternative, any other suitable semiconductor materials can be used for the substrate 402, for example semiconductor compound material such as gallium arsenide (GaAs), indium phosphide (InP), but also any suitable ternary semiconductor compound material or quaternary semiconductor compound material such as indium gallium arsenide (InGaAs).

Furthermore, as shown in FIG. 3, for the charge storing memory cell 406, 408, 410, 412, in each row, there is provided a control line (e.g. a respective word line). In an example, there are provided four control lines, e.g. a first word line CG0 302 coupled with and controlling the control gate of the first charge storing memory cell 406, a second word line CG1 304 coupled with and controlling the control gate of the second charge storing memory cell 408, a third word line CG2 306 coupled with and controlling the control gate of the third charge storing memory cell 410, and a fourth word line CG3 308 coupled with and controlling the control gate of the fourth charge storing memory cell 412. In an example, the control lines are running in a second direction (in FIGS. 3 and 4, the second direction is symbolized by means of a second arrow 416 (in FIG. 4, the second direction is perpendicular to the paper plane), which is different from the first direction. In an example, the first direction and the second direction may form an angle (in a common plane) in the range from about 20° to about 160°, e.g. in the range from about 40° to about 140°, e.g. in the range from about 60° to about 120°, e.g. in the range from about 80° to about 100°, e.g. in the range from about 85° to about 95°, e.g. about 90° (in this case, the first direction is perpendicular to the second direction).

Furthermore, a source line structure 420 is provided. In an embodiment, the source line structure 420 may include a second active area 422 disposed next to a charge storing memory cell (in FIGS. 3 and 4, e.g. between the second charge storing memory cell 408 and the third charge storing memory cell 410). The source line structure 420 may further include a select structure (e.g. a select gate structure) 424. In an embodiment, the select structure 424 may be disposed above the second active area 420 and may be configured to control a current flow through the second active area 422, e.g. using a field effect. In an embodiment, the select structure 424 may be arranged relative to the second active area 422 such that an inversion channel can be formed in the second active area 422 of the source line structure 420 in response to the application of a corresponding electrical potential to the select structure 424. As shown in FIG. 4, the select structure 424 may be coupled with the source side of the second charge storing memory cell 408 and with the source side of the third charge storing memory cell 410, thereby enabling a source-side injection programming of the second charge storing memory cell 408 or the third charge storing memory cell 410, as will be described in more detail below. Illustratively, the second active area 422 and the select structure 424 together form a transistor structure, e.g. a field effect transistor structure, which illustratively forms a controllable common source line shared by a plurality of connected charge storing memory cells.

In an embodiment, the source line structure 420 and therewith the second active area 422 and the select structure 424 are arranged such that they are running in the second direction. Thus, in an example, the source line structure 420 and the control lines 302, 304, 306, 308, are arranged in parallel with each other.

Furthermore, the second active area 422 is coupled to a predefined electrical potential (e.g. reference potential), e.g. to ground potential 310.

As shown in FIGS. 3 and 4, a first diffusion region 426 (e.g. implemented as a drain region) may be arranged in the first active area 418 on the opposite side of a charge storing region of the second charge storing memory cell 408 with respect to the second active area 422. Furthermore, a first contact via 430 (e.g. made of electrically conductive material such as e.g. tungsten (W)) may be provided in an inter layer dielectric 428 to provide an electrical contact with the first diffusion region 426.

As shown in FIGS. 3 and 4, the third charge storing memory cell 410 may be disposed next to the second active area 422 seen in the first direction.

A second diffusion region 432 (e.g. implemented as a drain region) may be arranged in the first active area 418 on the opposite side of a charge storing region of the third charge storing memory cell 410 with respect to the second active area 422. Furthermore, a second contact via 434 (e.g. made of electrically conductive material such as e.g. tungsten (W)) may be provided in the inter layer dielectric 428 to provide an electrical contact with the second diffusion region 432.

Furthermore, a plurality of metal lines (e.g. bit lines) may be provided (a first bit line BL0 312 and a second bit line BL1 314 are shown in FIG. 3), coupled to the corresponding via structure(s) in accordance with the respective layout of the memory cell field 202. In this example, the second bit line 314 may be electrically coupled to the first diffusion region 426 (e.g. by means of the first contact via 430) and to the second diffusion region 432 (e.g. by means of the second contact via 434). In an example, the metal lines BL0, BL1, 312, 314, are running in the first direction.

Furthermore, the memory cell arrangement 120 may include further metalization planes (in general an arbitrary number of metalization planes, depending on the respective requirements of the circuits to be formed) and corresponding inter-layer dielectric layers therebetween. However, these further metalization planes and further inter-layer dielectric layers are not shown in the figures for reasons of clarity.

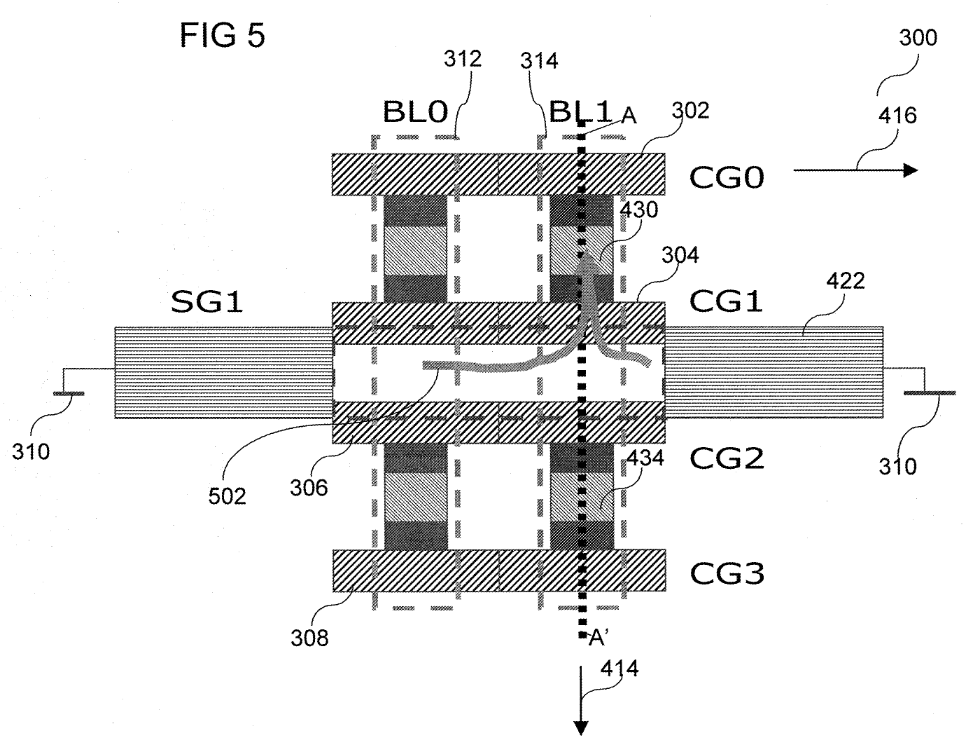

FIG. 5 shows a top view of a portion 300 of the memory cell field 202 of the memory cell arrangement 120 of FIG. 2 in accordance with an embodiment illustrating a read operation.

In the example shown in FIG. 5, it is assumed that the memory cell state of the second charge storing memory cell 408 should be read. Thus, the second charge storing memory cell 408 is selected for a read operation and the other charge storing memory cells 406, 412, 414, are unselected. In an example, the corresponding potentials or voltages may be provided by the memory cell arrangement controller 122 or by the memory-internal controller 220 or by another circuit such as e.g. by an additionally provided charge pump circuit (not shown).

The voltages applied to the corresponding control lines for reading are as follows:
unselected control lines, i.e., for example, first word line CG0 302, third word line CG2 306, and fourth word line CG3 308: V_{CG, unsel}≦V_{DD} (V_{DD}: supply voltage) or V_{CG, unsel}=0 V;
selected control line, i.e., for example, second word line CG1 304: V_{CG, sel}≦V_{DD} (V_{DD}: supply voltage) but V_{CG, sel}>0 V;
unselected select gate structures: V_{SG, unsel}=0 V;
selected select gate structure, i.e., e.g., select gate structure SG1 424: V_{SG, sel}>V_{DD} (V_{DD}: supply voltage), e.g. V_{SG, sel} in the range from about 6 V to about 10 V;
unselected bit lines, i.e., for example, first bit line BL0 312: V_{BL, unsel}≦0 V or V_{BL, unsel}=Floating;
selected bit line, i.e., for example, second bit line BL1 314: V_{BL, sel}>0 V, e.g. V_{BL, sel} in the range from about 0.1 V to about 1 V.

Depending on the programming state of the second charge storing memory cell 408 (and thus depending on the threshold voltage of the second charge storing memory cell 408), a corresponding current flow is caused by the application of the above voltages, wherein the current flow (technical current flow direction) is from the ground potential via the select gate structure SG1 424 (and thus through the second active area 422), through the first active area 418 portion of the second charge storing memory cell 408, via the first diffusion region 426 and the first contact via 430 into the second bit line BL1 314 and then to the connected sense amplifier, for example. This current flow is illustrated in FIG. 5 by means of a first current flow arrow 502.

Thus, in an embodiment, during the read operation, the select gate structures may be used to, on the one hand, generate the necessary electrical field to allow a current flow through the selected select gate structure and, on the other hand, to disconnect not selected charge storing memory cells during the read operation of the selected charge storing memory cell. Thus, a parasitic leakage current which may disturb read access may be reduced.

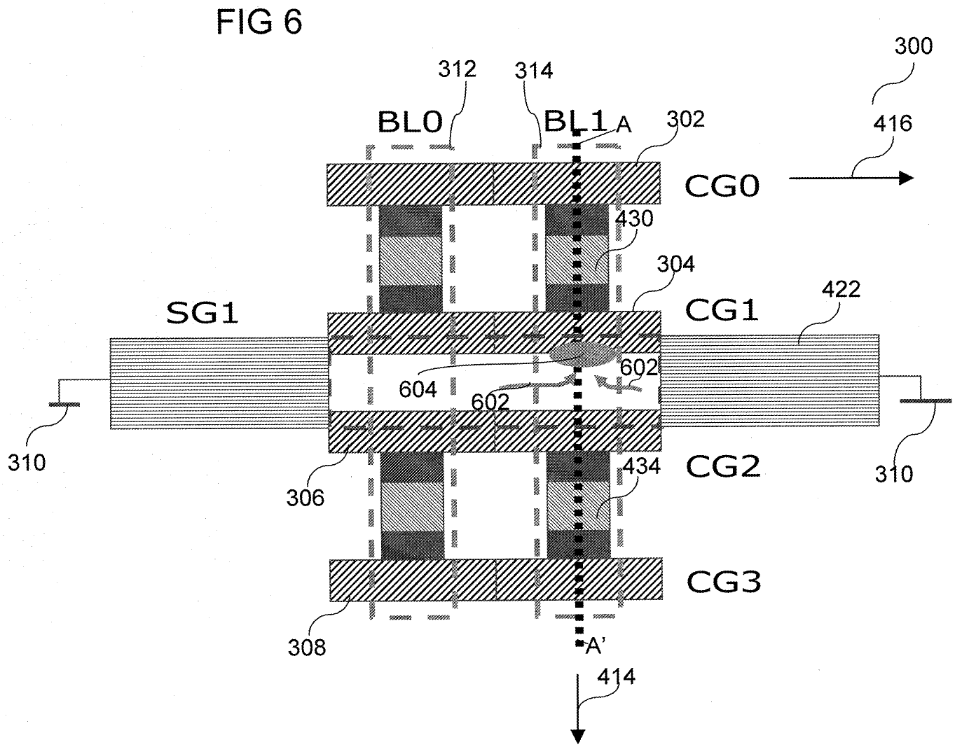

In the example shown in FIG. 6, it is assumed that the memory cell state of the second charge storing memory cell 408 should be programmed using source-side injection (SSI). Thus, the second charge storing memory cell 408 is selected for a programming operation in accordance with SSI and the other charge storing memory cells 406, 412, 414, are unselected. In an example, the corresponding potentials or voltages may be provided by the memory cell arrangement controller 122 or by the memory-internal controller 220 or by another circuit such as e.g. by an additionally provided charge pump circuit (not shown).

The voltages applied to the corresponding control lines for programming are as follows:
unselected control lines, i.e., for example, first word line CG0 302, third word line CG2 306, and fourth word line CG3 308: V_{CG, unsel}≦0 V or V_{CG, unsel}=e.g. about 8 V to about 12 V;
selected control line, i.e., for example, second word line CG1 304: V_{CG, sel}>0, e.g. V_{CG, sel}=e.g. about 8 V to about 12 V;
unselected select gate structures: V_{SG, unsel}=0 V;
selected select gate structure, i.e., e.g, select gate structure SG1 424: V_{SG, sel}>V_{t, SG} (V_{t, SG}: threshold voltage of the select gate structure SG1 424), and V_{SG, sel}≦V_{DD};
unselected bit lines, i.e., for example, first bit line BL0 312: V_{BL, unsel}≦0 V;
selected bit line, i.e., for example second bit line BL1 314: V_{BL, sel}>0 V, e.g. V_{BL, sel} in the range from about 3 V to about 5 V.

Depending on the programming state which should be programmed into the second charge storing memory cell 408 (and thus depending on the threshold voltage to be programmed or set of the second charge storing memory cell 408), a corresponding current flow (and charge storage) is caused by the application of the above voltages, wherein the current flow (technical current flow direction) is from the ground potential via the select gate structure SG1 424 (and thus through portions of the second active area 422), into a charge storage location 604 of the second charge storing memory cell 408. This current flow is illustrated in FIG. 6 by means of second current flow arrows 602.

Thus, in an embodiment, during the programming operation, the select gate structures are used to generate the necessary electrical field to allow a current flow through the selected select gate structure to program the selected charge storing memory cell.

Thus, illustratively, in various embodiments, the select gate structures provide and realize a source sided access to the channel of the respective (flash) memory cell. Furthermore, the select gate structures provide and realize a common source line by the inversion channel of the select gate structures (rather than by source implants as in conventional memory cell concepts).

Furthermore, various embodiments may provide a compact memory cell structure, which may use only a quarter of the select gate provided for a single physical bit compared with conventional memory cell concepts.

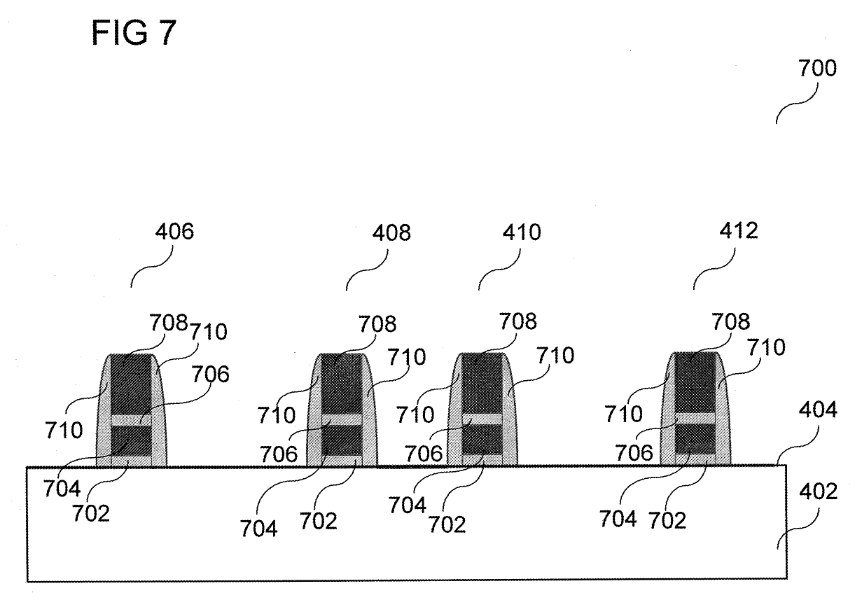

FIG. 7 shows a cross sectional view 700 of the portion of the memory cell field 202 of the memory cell arrangement 120 of FIG. 2 taken along a cross section line A-A′ in FIG. 3, in accordance with an embodiment at a first stage of its manufacturing.

First, the charge storing stacks (e.g. the floating gate stacks) of the memory cell arrangement to be formed are manufactured. In an example, a tunnel insulating layer 702 (e.g. a tunnel oxide layer, e.g. made of silicon oxide or made of a plurality of sublayers such as an oxide/nitride (ON) layer stack or an oxide/nitride/oxide (ONO) layer stack) having a layer thickness in the range from about 5 nm to about 15 nm, e.g. a layer thickness in the range from about 7 nm to about 12 nm, e.g. a layer thickness in the range from about 8 nm to about 10 nm may be deposited on the upper surface 404 of the substrate 402. Then, a floating gate layer (from which the floating gates 704 of the memory cells will be formed later on) made of electrically conductive material such as e.g. polysilicon or a metal may be deposited on the tunnel insulating layer 702. In an example, the floating gate layer may have a layer thickness in the range from about 50 nm to about 300 nm, e.g. a layer thickness in the range from about 100 nm to about 250 nm, e.g. a layer thickness in the range from about 150 nm to about 200 nm. Next, a control gate insulating layer 706 (e.g. made of an oxide such as e.g. silicon oxide or aluminum oxide) may be deposited on the floating gate layer. In an example, the control gate insulating layer 706 may have a layer thickness in the range from about 5 nm to about 40 nm, e.g. a layer thickness in the range from about 8 nm to about 30 nm, e.g. a layer thickness in the range from about 10 nm to about 20 nm. Then, a control gate layer (from which the control gates 708 of the memory cells will be formed later on) made of electrically conductive material such as e.g. polysilicon or a metal may be deposited on the control gate insulating layer 706. In an example, the control gate layer may have a layer thickness in the range from about 100 nm to about 1000 nm, e.g. a layer thickness in the range from about 300 nm to about 800 nm, e.g. a layer thickness in the range from about 500 nm to about 600 nm. Then, using an appropriately configured mask (not shown), the individual stacks are formed as shown in FIG. 7 by means of an anisotropic etching, for example, such as e.g. by means of an anisotropic dry etching such as e.g. reactive ion etching (RIE). In a subsequent process, an insulating material layer (from which the electrically insulating side wall spacers should be formed), e.g. made of an oxide such as e.g. silicon oxide, may be deposited on the resulting structure after the previous anisotropic etching. Using another anisotropic etching process, such as e.g. an anisotropic dry etching such as reactive ion etching (RIE), the insulating side wall spacers 710 may be formed, thereby forming charge storing memory cells 406, 408, 410, 412. By doing this, the upper surface 404 of the substrate 402 between the charge storing memory cells 406, 408, 410, 412, may be exposed. In an example, the insulating side wall spacers 710 may have a side wall thickness in the range from about 3 nm to about 70 nm, e.g. a side wall thickness in the range from about 5 nm to about 50 nm, e.g. a side wall thickness in the range from about 10 nm to about 30 nm.

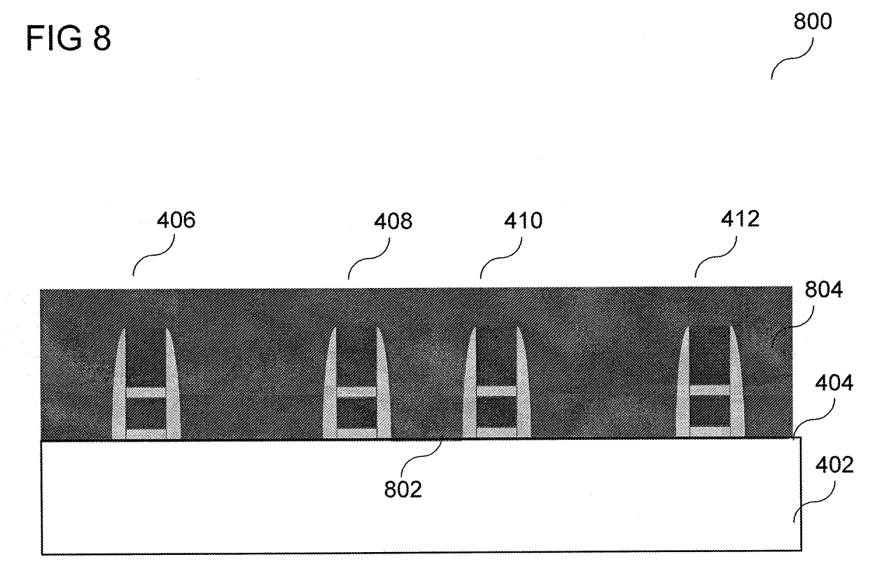

FIG. 8 shows a cross sectional view 800 of the portion of the memory cell field 202 of the memory cell arrangement 120 of FIG. 2 taken along a cross section line A-A′ in FIG. 3, in accordance with an embodiment at a second stage of its manufacturing.

Next, in the region of the second active area, a suitable threshold voltage implant (e.g. an n⁺ implant) may be provided to set the threshold voltage of the transistor like structure formed by the second active area 420, a select gate insulating layer 802 formed on the second active area 422, and the select gate structure 424. Then, a select gate insulating layer 802, e.g. a select gate oxide layer 802 (e.g. made of silicon oxide or an ON layer stack or an ONO layer stack), may be deposited between the second charge storing memory cells 408 and the third charge storing memory cells 410. The select gate insulating layer 802 may have a layer thickness in the range from about 5 nm to about 15 nm, e.g. a layer thickness in the range from about 8 nm to about 10 nm along the region in which the select gate structure 424 should be formed. Next, a select gate layer 804 may be deposited. The select gate layer 804 may be made of any suitable electrically conductive material such as e.g. polysilicon (doped or undoped) or electrically conductive carbon or a metal. The select gate layer 804 may have a layer thickness in the range from about 200 nm to about 2500 nm, e.g. a layer thickness in the range from about 500 nm to about 1500 nm, e.g. a layer thickness in the range from about 800 nm to about 1200 nm.

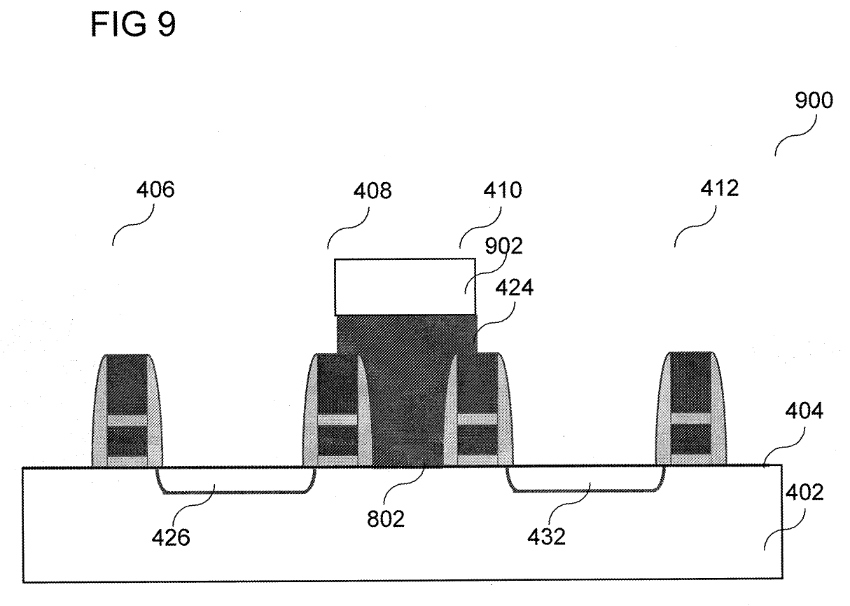

FIG. 9 shows a cross sectional view 900 of the portion of the memory cell field 202 of the memory cell arrangement 120 of FIG. 2 taken along a cross section line A-A′ in FIG. 3, in accordance with an embodiment at a third stage of its manufacturing.

In a subsequent process, using a suitable mask 902, the select gate structure 424 is patterned, e.g. by means of an anisotropic etching, e.g. an anisotropic dry etching such as e.g. RIE, thereby removing the material of the select gate layer 804 which is not covered by the mask 902. Furthermore, the diffusion regions 426, 432, may be formed by means of an ion implantation process (providing an n⁺ implantation, for example).

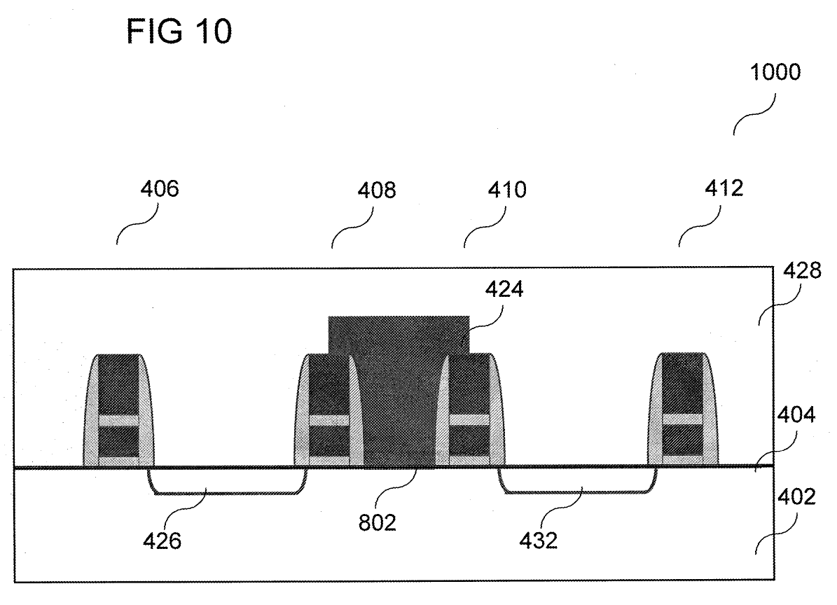

FIG. 10 shows a cross sectional view 1000 of the portion of the memory cell field 202 of the memory cell arrangement 120 of FIG. 2 taken along a cross section line A-A′ in FIG. 3, in accordance with an embodiment at a fourth stage of its manufacturing.

Then, an inter layer dielectric 428 (e.g. made of an oxide (e.g. silicon oxide) or a nitride (e.g. silicon nitride) or a low-k dielectric (e.g. having a dielectric constant lower than silicon oxide)) may be deposited on the structure 900 shown in FIG. 9.

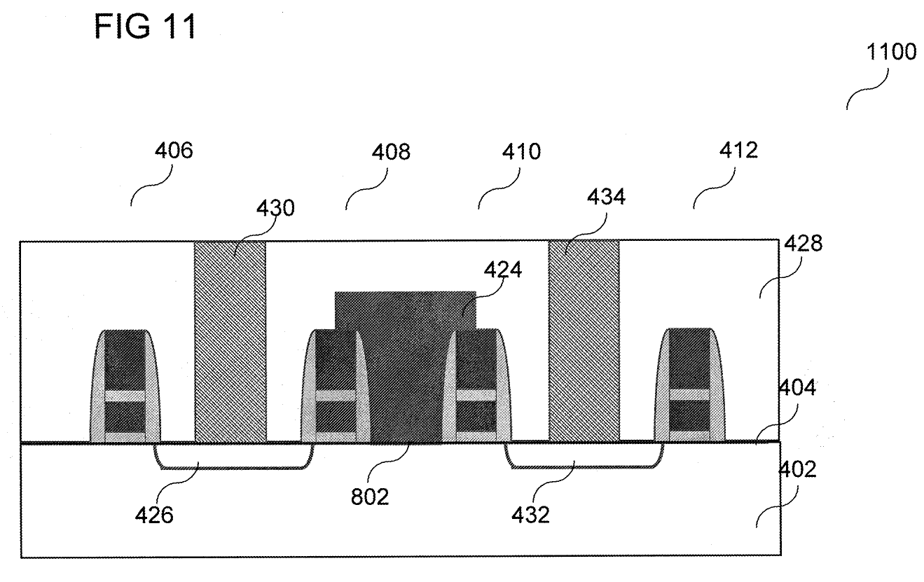

FIG. 11 shows a cross sectional view 1100 of the portion of the memory cell field 202 of the memory cell arrangement 120 of FIG. 2 taken along a cross section line A-A′ in FIG. 3, in accordance with an embodiment at a fifth stage of its manufacturing.

Then, contact holes may be etched (e.g. using an anisotropic etching, e.g. using an anisotropic dry etching such as e.g. RIE) in the inter layer dielectric 428 above the diffusion regions 426, 432, followed by a process filling the contact holes with electrically conductive material, e.g. a metal such as e.g. tungsten (W), thereby forming the contact vias 430, 434. The contact vias 430, 434 provide an electrical contact with the diffusion regions 426, 432.

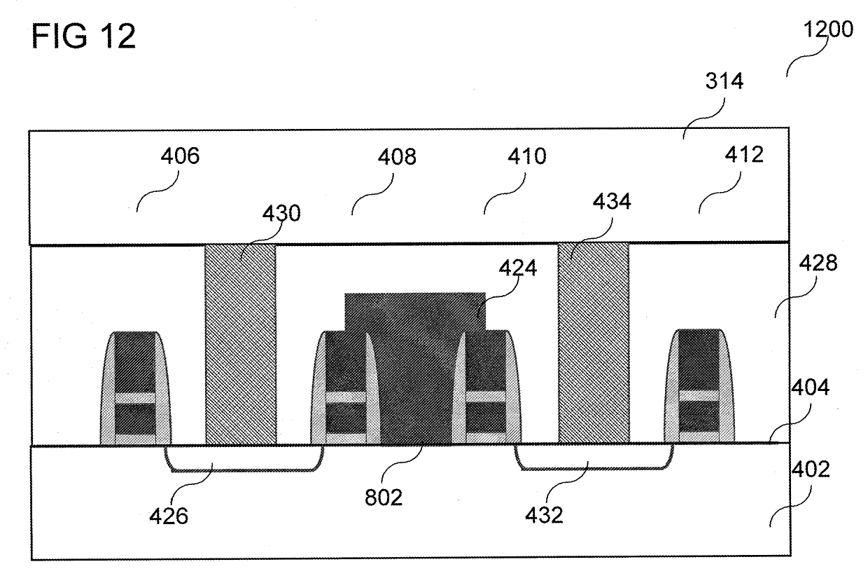

FIG. 12 shows a cross sectional view 1200 of the portion of the memory cell field 202 of the memory cell arrangement 120 of FIG. 2 taken along a cross section line A-A′ in FIG. 3, in accordance with an embodiment at a sixth stage of its manufacturing.

Then, e.g. using a damascene process, the bit lines (e.g. including bit line 314) may be formed by depositing and patterning electrically conductive material such as e.g. a metal, e.g. copper or aluminium. The bit line 314 is electrically coupled with the contact vias 430, 434 to allow a control of the programming/erasing/reading of the connected memory cells.

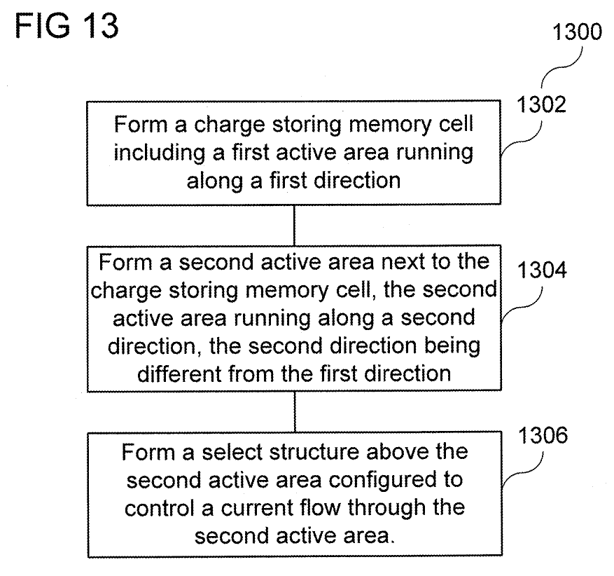

FIG. 13 shows a flow diagram 1300 illustrating a method for manufacturing a memory cell arrangement in accordance with an embodiment.

In 1302, a charge storing memory cell may be formed including a first active area running along a first direction. In 1304, a second active area may be formed next to the charge storing memory cell, the second active area running along a second direction, the second direction being different from the first direction. Then, in 1306, a select structure may be formed above the second active area configured to control a current flow through the second active area.

In an example of this embodiment, the second active area may be formed on the source side of the charge storing memory cell.

In another example of this embodiment, the second active area may be coupled to a predefined electrical potential, e.g. to a ground potential.

In yet another example of this embodiment, the charge storing memory cell may be a charge trapping memory cell or a floating gate memory cell.

In yet another example of this embodiment, the method may further include forming a diffusion region (e.g. as a drain region of the charge storing memory cell) in the first active area on the opposite of a charge storing region of the charge storing memory cell with respect to the second active area.

In yet another example of this embodiment, the method may further include forming a via structure coupled to the diffusion region.

In yet another example of this embodiment, the method may further include forming a metal line coupled to the via structure.

In yet another example of this embodiment, the metal line may be formed such that it is running in the first direction.

In yet another example of this embodiment, the second direction may be perpendicular to the first direction.

In yet another example of this embodiment, the second active area and the select structure together form a transistor structure.

In yet another example of this embodiment, the second active area may be formed such that it is crossing the first active area.

In yet another example of this embodiment, the method may further include forming a further charge storing memory cell next to the second active area in the first direction.

In yet another example of this embodiment, the second active area may be formed on the source side of the further charge storing memory cell.

In yet another example of this embodiment, the further charge storing memory cell may be a charge trapping memory cell or a floating gate memory cell.

In yet another example of this embodiment, the method may further include forming a further diffusion region (e.g. as a drain region of the further charge storing memory cell) in the first active area on the opposite of a charge storing region of the further charge storing memory cell with respect to the second active area.

In yet another example of this embodiment, the method may further include forming a further via structure coupled to the further diffusion region.

In yet another example of this embodiment, the metal line may be coupled to the further via structure.

In yet another example of this embodiment, the method may further include forming a programming controller configured to program the charge storing memory cell in accordance with a source side injection programming.

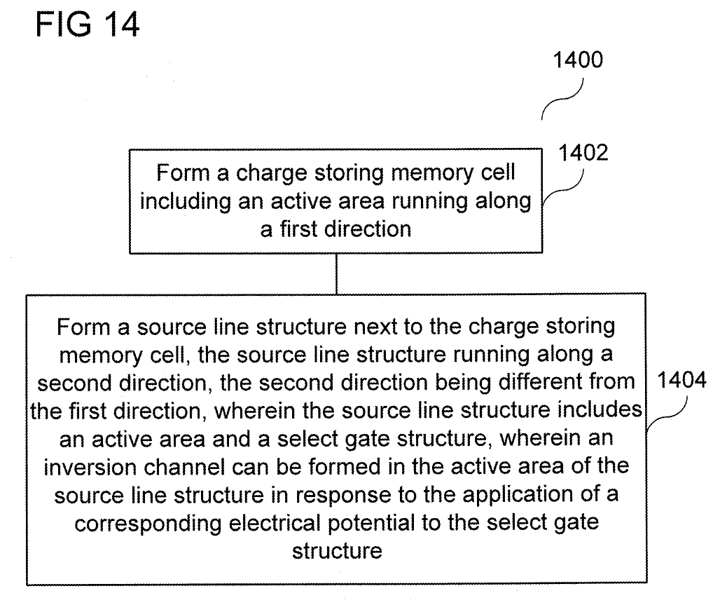

FIG. 14 shows a flow diagram 1400 illustrating a method for manufacturing a memory cell arrangement in accordance with another embodiment.

In 1402, a charge storing memory cell may be formed including an active area running along a first direction. In 1402, a source line structure may be formed next to the charge storing memory cell, the source line structure running along a second direction, the second direction being different from the first direction. The source line structure may include an active area and a select gate structure, wherein an inversion channel can be formed in the active area of the source line structure in response to the application of a corresponding electrical potential to the select gate structure.

In an example of this embodiment, the active area of the source line structure may be formed on the source side of the charge storing memory cell.

In another example of this embodiment, the active area of the source line structure may be coupled to a predefined electrical potential, e.g. to a ground potential.

In yet another example of this embodiment, the charge storing memory cell is a charge trapping memory cell or a floating gate memory cell.

In yet another example of this embodiment, the method may further include forming a diffusion region (e.g. a drain region of the charge storing memory cell) in the active area on the opposite side of a charge storing region of the charge storing memory cell with respect to the active area of the source line structure.

In yet another example of this embodiment, the method may further include forming a via structure coupled to the diffusion region.

In yet another example of this embodiment, the method may further include forming a metal line coupled to the via structure.

In yet another example of this embodiment, the metal line may be formed such that it is running in the first direction.

In yet another example of this embodiment, the second direction may be perpendicular to the first direction.

In yet another example of this embodiment, the active area of the source line structure and the select gate structure of the source line structure together may form a transistor structure.

In yet another example of this embodiment, the active area of the source line structure may be formed such that it is crossing the active area.

In yet another example of this embodiment, the method may further include forming a further charge storing memory cell next to the active area of the source line structure in the first direction.

In yet another example of this embodiment, the active area of the source line structure may be formed on the source side of the further charge storing memory cell.

In yet another example of this embodiment, the further charge storing memory cell may be a charge trapping memory cell or a floating gate memory cell.

In yet another example of this embodiment, the method may further include forming a further diffusion region (e.g. as a drain region of the further charge storing memory cell) in the active area on the opposite of a charge storing region of the further charge storing memory cell with respect to the active area of the source line structure.

In yet another example of this embodiment, the method may further include forming a further via structure coupled to the further diffusion region.

In yet another example of this embodiment, the metal line may be coupled to the further via structure.

In yet another example of this embodiment, the method may further include forming a programming controller configured to program the charge storing memory cell in accordance with a source side injection programming.

In another embodiment, a memory cell arrangement is provided. The memory cell arrangement may include a plurality of charge storing memory cells, and a source line structure shared by the plurality of charge storing memory cells, wherein the source line structure includes an active area and a select gate structure, wherein an inversion channel can be formed in the active area of the source line structure in response to the application of a corresponding electrical potential to the select gate structure.

In another embodiment, a memory cell arrangement is provided. The memory cell arrangement may include a charge storing memory cell including a first active area running along a first direction, a second active area disposed next to the charge storing memory cell, the second active area running along a second direction, the second direction being different from the first direction, and a select structure disposed above the second active area configured to control a current flow through the second active area.

In an example of this embodiment, the second active area may be disposed on the source side of the charge storing memory cell.

In another example of this embodiment, the second active area may be coupled to a predefined electrical potential, e.g. to a ground potential.

In yet another example of this embodiment, the charge storing memory cell may be a charge trapping memory cell or a floating gate memory cell.

In yet another example of this embodiment, the memory cell arrangement may further include a diffusion region (e.g. a drain region of the charge storing memory cell) arranged in the first active area on the opposite of a charge storing region of the charge storing memory cell with respect to the second active area.

In yet another example of this embodiment, the memory cell arrangement may further include a via structure coupled to the diffusion region.

In yet another example of this embodiment, the memory cell arrangement may further include a metal line coupled to the via structure.

In yet another example of this embodiment, the metal line may be running in the first direction.

In yet another example of this embodiment, the second direction may be perpendicular to the first direction.

In yet another example of this embodiment, the second active area and the select structure together may form a transistor structure.

In yet another example of this embodiment, the second active area may cross the first active area.

In yet another example of this embodiment, the memory cell arrangement may further include a further charge storing memory cell disposed next to the second active area in the first direction.

In yet another example of this embodiment, the second active area is disposed on the source side of the further charge storing memory cell.

In yet another example of this embodiment, the further charge storing memory cell may be a charge trapping memory cell or a floating gate memory cell.

In yet another example of this embodiment, the memory cell arrangement may further include a further diffusion region (e.g. a drain region of the further charge storing memory cell) arranged in the first active area on the opposite of a charge storing region of the further charge storing memory cell with respect to the second active area.

In yet another example of this embodiment, the memory cell arrangement may further include a further via structure coupled to the further diffusion region.

In yet another example of this embodiment, the metal line may be coupled to the further via structure.

In yet another example of this embodiment, the memory cell arrangement may further include a programming controller configured to program the charge storing memory cell in accordance with a source side injection programming.

In another embodiment, a memory cell arrangement is provided. The memory cell arrangement may include a charge storing memory cell including an active area running along a first direction, and a source line structure disposed next to the charge storing memory cell, the source line structure running along a second direction, the second direction being different from the first direction. The source line structure may include an active area and a select gate structure, wherein an inversion channel can be formed in the active area of the source line structure in response to the application of a corresponding electrical potential to the select gate structure.

In an example of this embodiment, the active area of the source line structure may be disposed on the source side of the charge storing memory cell.

In another example of this embodiment, the active area of the source line structure is coupled to a predefined electrical potential, e.g. to a ground potential.

In yet another example of this embodiment, the charge storing memory cell may be a charge trapping memory cell or a floating gate memory cell.

In yet another example of this embodiment, the memory cell arrangement may further include a diffusion region (e.g. a drain region of the charge storing memory cell) arranged in the active area on the opposite of a charge storing region of the charge storing memory cell with respect to the active area of the source line structure.

In yet another example of this embodiment, the memory cell arrangement may further include a via structure coupled to the diffusion region.

In yet another example of this embodiment, the memory cell arrangement may further include a metal line coupled to the via structure.

In yet another example of this embodiment, the metal line may run in the first direction.

In yet another example of this embodiment, the second direction may be perpendicular to the first direction.

In yet another example of this embodiment, the active area of the source line structure and the select gate structure of the source line structure together may form a transistor structure.

In yet another example of this embodiment, the active area of the source line structure may cross the active area.

In yet another example of this embodiment, the memory cell arrangement may further include a further charge storing memory cell disposed next to the active area of the source line structure in the first direction.

In yet another example of this embodiment, the active area of the source line structure may be disposed on the source side of the further charge storing memory cell.

In yet another example of this embodiment, the further charge storing memory cell may be a charge trapping memory cell or a floating gate memory cell.

In yet another example of this embodiment, the memory cell arrangement may further include a further diffusion region (e.g. a drain region of the further charge storing memory cell) arranged in the active area on the opposite of a charge storing region of the further charge storing memory cell with respect to the active area of the source line structure.

In yet another example of this embodiment, the memory cell arrangement may further include a further via structure coupled to the further diffusion region.

In yet another example of this embodiment, the metal line may be coupled to the further via structure.

In yet another example of this embodiment, the memory cell arrangement may further include a programming controller configured to program the charge storing memory cell in accordance with a source side injection programming.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A memory cell arrangement, comprising:
a charge storing memory cell comprising a first active area running along a first direction;
a second active area disposed next to the charge storing memory cell, the second active area running along a second direction, the second direction being different from the first direction; and
a select structure disposed above the second active area configured to control a current flow through the second active area.

2. The memory cell arrangement of claim 1,
wherein the second active area is disposed on the source side of the charge storing memory cell.

3. The memory cell arrangement of claim 1,
wherein the second active area is coupled to a predefined electrical potential.

4. The memory cell arrangement of claim 1,
wherein the charge storing memory cell is a charge trapping memory cell.

5. The memory cell arrangement of claim 1,
wherein the charge storing memory cell is a floating gate memory cell.

6. The memory cell arrangement of claim 1, further comprising:
a diffusion region arranged in the first active area on the opposite side of a charge storing region of the charge storing memory cell with respect to the second active area.

7. The memory cell arrangement of claim 6, further comprising:
a via structure coupled to the diffusion region.

8. The memory cell arrangement of claim 7, further comprising:
a metal line coupled to the via structure.

9. The memory cell arrangement of claim 8,
wherein the metal line is running in the first direction.

10. The memory cell arrangement of claim 1,
wherein the second direction is perpendicular to the first direction.

11. The memory cell arrangement of claim 1, further comprising:
a further charge storing memory cell disposed next to the second active area in the first direction.

12. The memory cell arrangement of claim 11,
wherein the second active area is disposed on the source side of the further charge storing memory cell.

13. The memory cell arrangement of claim 11, further comprising:
a further diffusion region arranged in the first active area on the opposite of a charge storing region of the further charge storing memory cell with respect to the second active area.

14. The memory cell arrangement of claim 1, further comprising:
a programming controller configured to program the charge storing memory cell in accordance with a source side injection programming.

15. A memory cell arrangement, comprising:
a charge storing memory cell comprising an active area running along a first direction; and
a source line structure disposed next to the charge storing memory cell, the source line structure running along a second direction, the second direction being different from the first direction;
wherein the source line structure comprises an active area and a select gate structure, wherein an inversion channel can be formed in the active area of the source line structure in response to the application of a corresponding electrical potential to the select gate structure.

16. The memory cell arrangement of claim 15,
wherein the active area of the source line structure is disposed on the source side of the charge storing memory cell.

17. The memory cell arrangement of claim 15,
wherein the active area of the source line structure is coupled to a predefined electrical potential.

18. The memory cell arrangement of claim 15,
wherein the charge storing memory cell is a floating gate memory cell.

19. The memory cell arrangement of claim 15, further comprising:
a programming controller configured to program the charge storing memory cell in accordance with a source side injection programming.

20. A method for manufacturing a memory cell arrangement, the method comprising:
forming a charge storing memory cell comprising a first active area running along a first direction;
forming a second active area next to the charge storing memory cell, the second active area running along a second direction, the second direction being different from the first direction; and
forming a select structure above the second active area configured to control a current flow through the second active area.

21. The method of claim 20,
wherein the second active area is formed on the source side of the charge storing memory cell.

22. The method of claim 20, further comprising:
forming a programming controller configured to program the charge storing memory cell in accordance with a source side injection programming.

23. A method for manufacturing a memory cell arrangement, comprising:
forming a charge storing memory cell comprising an active area running along a first direction; and
forming a source line structure next to the charge storing memory cell, the source line structure running along a second direction, the second direction being different from the first direction;
wherein the source line structure comprises an active area and a select gate structure, wherein an inversion channel can be formed in the active area of the source line structure in response to the application of a corresponding electrical potential to the select gate structure.

24. The method of claim 23,
wherein the active area of the source line structure is formed on the source side of the charge storing memory cell.

25. A memory cell arrangement, comprising:
a plurality of charge storing memory cells; and
a source line structure shared by the plurality of charge storing memory cells;
wherein the source line structure comprises an active area and a select gate structure,
wherein an inversion channel can be formed in the active area of the source line structure in response to the application of a corresponding electrical potential to the select gate structure.
